(19) United States
(12) Patent Application Publication
(10) Pub. No.: US 2022/0208604 A1
(43) Pub. Date: Jun. 30, 2022

(54) PROTECTION OF SEED LAYERS DURING ELECTRODEPOSITION OF METALS IN SEMICONDUCTOR DEVICE MANUFACTURING

(71) Applicant: Lam Research Corporation, Fremont, CA (US)

(72) Inventors: Huanfeng Zhu, West Linn, OR (US); Jonathan David Reid, Sherwood, OR (US); Jian Zhou, Portland, OR (US); Tariq Majid, West Linn, OR (US)

(21) Appl. No.: 17/594,716

(22) PCT Filed: Apr. 24, 2020
(86) PCT No.: PCT/US2020/029908

§ 371 Date: Oct. 27, 2021

Related U.S. Application Data
(60) Provisional application No. 62/841,522, filed on May 1, 2019.

(51) Int. Cl. H01L 21/768; C25D 7/12; C25D 3/38; C23C 18/16; H01L 23/532; C23C 16/02; C23C 16/16

(52) U.S. Cl. CPC H01L 21/76873; H01L 21/76846; H01L 21/76877; H01L 21/76876; C25D 7/123; C23C 16/16; C23C 18/1621; C23C 18/1675; H01L 23/53238; C23C 16/0281; C25D 3/38

(57) ABSTRACT

A protective layer is formed over a copper seed layer on a semiconductor substrate prior to electroplating. The protective layer is capable of protecting the copper seed layer from oxidation and from dissolution in an electrolyte during initial phases of electroplating. The protective layer, in some embodiments, prevents the copper seed layer from contacting atmosphere, and from being oxidized by atmospheric oxygen and/or moisture. The protective layer contains a metal that is less noble than copper (e.g., cobalt), where the metal can be in an oxidized form that is readily soluble in a plating liquid. In one embodiment a protective cobalt layer is formed by depositing cobalt metal by chemical vapor deposition over copper seed layer without exposing the copper seed layer to atmosphere, followed by subsequent oxidation of cobalt to cobalt oxide that occurs after the substrate is exposed to atmosphere. The resulting protective layer is dissolved during electroplating.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### FIELD

The present disclosure relates generally to electroplating of metal layers on a semiconductor substrate. More particularly, it relates to protection of copper seed layers during electroplating of copper in Damascene processing.

### BACKGROUND

Damascene processing is a method for forming metal lines on integrated circuits. It involves formation of inlaid metal lines in trenches and vias formed in a dielectric layer (inter metal dielectric). Damascene processing is often a preferred method because it requires fewer processing steps than other methods and offers a higher yield. It is also particularly well-suited to metals such as copper that cannot be readily patterned by plasma etching.

In a typical Damascene process flow, metal (such as copper) is electroplated onto a patterned dielectric, to fill the vias and trenches formed in the dielectric layer. The resulting metallization layer is typically formed either directly on a layer carrying active devices or on another metallization layer. A stack of several metallization layers can be formed using Damascene processing. The metal-filled lines of this stack serve as conducting paths of an integrated circuit.

Before the metal is deposited into the vias and trenches of the patterned dielectric, the dielectric layer is lined with a thin layer of diffusion barrier material (e.g., TaNx, TiNx, or WNx), and, subsequently, with a thin layer of conductive seed layer material (e.g., Cu). The diffusion barrier layer protects inter-metal dielectric (IMD) and active devices from diffusion of copper and other readily diffusing metals into these regions. The seed layer (e.g., Cu seed layer) serves as a conductive layer to which electrical contact is made during copper electrofill operation. A wetting layer, such as Ti, Ta, or Co layer can be sandwiched between the diffusion barrier layer and the seed layer to promote adhesion between the diffusion barrier material and the seed layer material.

During copper electroplating, electrical contact is made to the conductive seed layer, typically at the periphery of the substrate. The substrate is cathodically biased and is immersed into an electrolyte that contains copper ions and, typically, an acid and organic electroplating additives that promote filling of damascene features.

During electroplating, the copper ions contained in the electrolyte are reduced at the cathodically biased substrate, such that copper is electrodeposited on the conductive seed layer according to equation (1).

$$Cu 2 + + 2 e - \to Cu \qquad ( 1 )$$

The sizes of recessed features that need to be filled in the Damascene process become smaller with the ongoing miniaturization of the devices.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

The integrity of the conductive seed layer is important for successful defect-free electrodeposition. If the seed layer is damaged or is discontinuous, the electroplating can result in the formation of voids. This problem is particularly pronounced during electrodeposition conducted on thin seed layers that are needed for narrow recessed features. In various aspects of the invention, these problems are addressed by protecting the seed layers by a sacrificial film that dissolves during the electroplating.

In one aspect, a method of processing a semiconductor substrate is provided. In some embodiments the method includes: (a) providing a semiconductor substrate, wherein the provided semiconductor substrate has at least one recessed feature (e.g., a trench and/or a via) and includes an exposed copper seed layer at least on the sidewalls of the at least one recessed feature; and (b) forming a protective layer over the copper seed layer, where the protective layer comprises a metal that is less noble than copper. Examples of such metals include cobalt, tin, zinc, and iron, where the metal may be in zero and/or non-zero oxidation state. In some embodiments, the substrate provided in (a) further includes a cobalt adhesion layer underlying the copper seed layer, and a diffusion barrier layer underlying the cobalt adhesion layer. In some embodiments, the width of the at least one recessed feature is about 20 nm or less.

In one embodiment the protective layer is a cobalt layer. The protective cobalt layer may include cobalt oxide, cobalt in zero oxidation state or a mixture of cobalt in zero oxidation state with cobalt oxide. In some embodiments the cobalt protective layer is formed using chemical vapor deposition (CVD) or atomic layer deposition (ALD). In other embodiments the cobalt protective layer is formed using physical vapor deposition (PVD). In some embodiments formation of the cobalt protective layer includes oxidation of deposited cobalt to form cobalt-oxygen bonds upon exposure of the substrate to air.

In one implementation the substrate processing method includes depositing the copper seed layer to provide a substrate having an exposed copper seed layer, followed by depositing a cobalt protective layer, such that the substrate is not exposed to atmosphere after the copper seed layer has been deposited and before the cobalt protective layer is deposited. In a specific implementation the copper seed layer is deposited by PVD, and the cobalt protective layer is deposited by CVD, without an air break between the two depositions.

In some embodiments the protective layer is deposited conformally and covers the copper seed layer at the sidewalls of the at least one recessed feature. In other embodiments, the protective layer is deposited over a field region of the semiconductor substrate such that it covers an opening of the at least one recessed feature and thereby prevents the copper seed layer on the sidewalls of the at least one recessed feature from contacting atmosphere.

In some embodiments after the protective layer has been deposited, the substrate is exposed to atmosphere, and copper is electroplated into the at least one recessed feature, such that the protective layer is substantially dissolved during the electrodeposition of copper. For example if the protective layer is a cobalt protective layer, at least some of the deposited cobalt typically oxidizes upon exposure to atmosphere to form cobalt-oxygen bonds.

In some embodiments the thickness of the protective layer formed over the copper seed layer is between about 10-50 Å. In one example, the thickness of the protective layer formed over the copper seed layer is between about 10-20 Å, and the thickness of the copper seed layer is between about 20-30 Å at the sidewalls of the at least one recessed feature.

In another aspect a method of electrodepositing copper into a recessed feature on a semiconductor substrate is provided. The method includes providing a semiconductor substrate having a protective layer into an electroplating apparatus and electrodepositing copper onto the substrate, such that the protective layer is substantially dissolved during the electrodeposition operation (typically during the initial contact of the substrate with the electrolyte). In some embodiments the semiconductor substrate used for electroplating includes at least one recessed feature lined with a copper seed layer, and the semiconductor substrate includes an exposed protective layer overlying the copper seed layer, wherein the protective seed layer comprises a metal that is less noble than copper. The substrate is contacted with an acidic electrolyte containing copper ions, and is cathodically biased, such that the protective layer is substantially dissolved, and copper is electroplated into the at least one recessed feature. In some implementations the metal that is less noble than copper is cobalt, and cobalt forms cobalt-oxygen bonds in the protective layer prior to electroplating. In some implementations the protective layer has a thickness of between about 10-50 Å. In some embodiments, electroplating includes initially contacting the semiconductor substrate with the acidic electrolyte without biasing the semiconductor substrate. In some embodiments the at least one recessed feature has a width of between about 7-14 nm. For example in one implementation the at least one recessed feature has a width of between about 7-14 nm, and the protective layer has a thickness of between about 1-2 nm on the sidewalls of the at least one recessed feature.

All provided methods can be integrated with photolithographic processing schemes, and may further include: applying photoresist to the semiconductor substrate; exposing the photoresist to light; patterning the photoresist and transferring the pattern to the semiconductor substrate; and selectively removing the photoresist from the semiconductor substrate.

In another aspect, an apparatus for processing a semiconductor substrate is provided, where the apparatus includes: (a) one or more process chambers configured for deposition of metals; and (b) a controller comprising program instructions for causing deposition of a protective layer comprising a metal that is less noble than copper over a copper seed layer on the semiconductor substrate. In one implementation the metal that is less noble than copper is cobalt, and the program instructions include instructions for causing deposition of cobalt by using a reaction of a cobalt-containing precursor (e.g., in a CVD or ALD process chamber). In some embodiments the controller includes program instructions for depositing the protective layer to a thickness of between about 10-50 Å.

The controller may further include program instructions for causing a deposition of a copper seed layer prior to deposition of the protective layer. In some embodiments, the apparatus includes a PVD process chamber configured for deposition of the copper seed layer, and a CVD or ALD process chamber configured for deposition of the protective layer, wherein the apparatus is configured for transferring the semiconductor substrate from the PVD process chamber to the CVD or ALD process chamber without exposing the semiconductor substrate to atmosphere.

According to another aspect, a system is provided herein which includes any of the apparatuses provided herein and a stepper.

According to another aspect, a non-transitory computer machine-readable medium is provided. It includes program instructions for control of a deposition apparatus and/or electroplating apparatus, and can include code for performing any of the methods provided herein. In some embodiments code is provided for: (a) depositing a copper seed layer on a substrate having at least one recessed feature; and (b) without exposing the substrate to atmosphere, depositing a protective layer over the copper seed layer.

According to another aspect a partially fabricated semiconductor device is provided, wherein the semiconductor device comprises a plurality of recessed features formed in a dielectric layer, wherein the substrate includes an exposed cobalt layer overlying a copper seed layer.

These and other features and advantages of the present disclosure will be described in more detail below with reference to the associated drawings.

### BRIEF DESCRIPTION OF THE DRAWINGS

FIGS. 1A-ID show schematic cross-sectional views of a semiconductor substrate during processing according to an embodiment provided herein.

FIG. 2 is a process flow diagram for a process in accordance with an embodiment provided herein.

FIGS. 3A-3D show schematic cross-sectional views of a semiconductor substrate during processing according to an embodiment provided herein.

FIG. 4 is a process flow diagram for a process in accordance with an embodiment provided herein.

FIG. 5 is a schematic presentation of a process chamber that is suitable for a deposition of a protective layer in accordance with an embodiment provided herein.

FIG. 6 is a schematic illustration of a processing apparatus suitable for deposition processes in accordance with disclosed embodiments.

FIG. 7 shows a schematic view of a multi-station processing system according to an embodiment provided herein.

### DETAILED DESCRIPTION

Methods for protecting copper seed layers are provided. The methods can be used to protect copper seed layers from undesired oxidation in atmosphere and from dissolution in an acidic electrolyte. The methods can be used on a variety of semiconductor substrates, but are particularly advantageous for semiconductor substrates having narrow recessed features, such as recessed features with widths of less than about 20 nm (referring to width after copper seed layer has been deposited), such as less than about 15 nm, e.g., with widths of between about 7-14 nm, or between about 7-10 nm. Substrates with narrow features typically require thin copper seed layers (e.g., 1-3 nm thick layers), which particularly benefit from the protective methods provided herein. When copper seed layers are exposed to atmosphere, copper can be oxidized to form copper oxide. If the copper seed layer is relatively thick, copper oxide is typically formed only on the surface of the copper metal, and the copper seed layer can still perform its function. However, when thin copper seed layers, e.g., 0.5-2 nm thick seed layers are exposed to atmosphere, copper oxide can be formed throughout the entire film depth, thereby resulting in a fully discontinuous seed layer. During the initial stages of electroplating, copper oxide can be dissolved in an acidic electrolyte and underlying layers may be exposed, which in turn leads to differences in nucleation of electroplated copper. Further, even if copper seed layer is oxidized only on the surface and still contains copper metal, the fast rate of copper oxide dissolution in an acidic electrolyte would lead to a loss of a considerable amount of seed layer material. In addition, when very thin seed layers are used, the variation in seed layer thickness and oxidation can be large relative to the initial seed layer thickness. These variations can lead to large variations in nucleation rates of copper during electroplating. Undesired oxidation of copper seed layers typically results in the formation of voids during electroplating, which are particularly pronounced in the vicinity of sidewalls of damascene features, where the copper seed layers are typically the thinnest.

While in some cases copper oxide can be reduced to copper metal by exposing the substrate to a reducing agent, such as by using a reducing plasma treatment, this treatment can still lead to copper loss and may not be sufficient to mitigate all problems. For example, copper seed layer oxidation may in some cases lead to oxidation of an underlying diffusion barrier layer. Even if copper oxide is reduced by a hydrogen plasma treatment before electroplating, this treatment would not be sufficient to reduce the oxidized barrier material. Further, the adhesion between oxidized diffusion barrier material and the copper seed layer would be weakened. These problems can be mitigated by protecting the copper seed layers from oxidation using sacrificial protective layers, as described herein.

The methods involve forming a protective layer over a copper seed layer on a semiconductor substrate having one or more recessed features. The protective layer includes a metal that is less noble than copper (e.g., cobalt, zinc, tin, or iron), where the metal may be in an oxidized form (e.g., cobalt oxide, zinc oxide, tin oxide, or iron oxide). For example, a protective cobalt layer may be formed over copper seed layer by first depositing cobalt metal (in zero oxidation state) using CVD or PVD, followed by exposing the substrate to atmosphere and allowing cobalt to be oxidized to cobalt oxide. The protective layer is sacrificial and is allowed to dissolve in an electrolyte during early stages of electroplating. The protective seed layer may include metal in zero oxidation state and/or oxidized metal (e.g., metal oxide), where the protective seed layer chemistry is selected such that it would be soluble in the plating electrolyte.

For example, metal in zero oxidation state (as long as the metal is less noble than copper), can dissolve via a displacement reaction, or via oxidation in an acid. For example, cobalt in zero oxidation state may be dissolved in accordance with equation (2) or (3):

$$\begin{matrix}Co + Cu 2 + \to Cu + Co 2 + & ( 2 ) \\ Co + 4 H + + O 2 \to Co 2 + + 2 H 2 O & ( 3 )\end{matrix}$$

Metal oxides (such as cobalt oxide) will also be soluble in acidic plating solutions. After the protective layer is dissolved, the underlying copper seed layer is exposed, and metal (e.g., copper) is electroplated onto the exposed copper seed layer. Such protection can lead to a significant reduction in the corrosion of copper seed layer and of underlying layers, and, consequently, in a reduced number of voids and defects in the electroplated layers.

The term “semiconductor substrate” as used herein refers to a substrate at any stage of semiconductor device fabrication containing a semiconductor material anywhere within its structure. It is understood that the semiconductor material in the semiconductor substrate does not need to be exposed. Semiconductor wafers having a plurality of layers of other materials (e.g., dielectrics) covering the semiconductor material, are examples of semiconductor substrates. The following detailed description assumes the disclosed implementations are implemented on a semiconductor wafer, such as on a 200 mm, 300 mm, or 450 mm semiconductor wafer. However, the disclosed implementations are not so limited. The work piece may be of various shapes, sizes, and materials. In addition to semiconductor wafers, other work pieces that may take advantage of the disclosed implementations include various articles such as printed circuit boards and the like.

The term “about” when used in reference to numerical values includes a range of ±10% of the recited numerical value, unless otherwise specified.

The term “copper seed layer” refers to layers that include copper, and encompasses both pure copper, and copper alloys, such as copper manganese alloys. In some embodiments copper content in the copper seed layer is at least about 50%, such as at least about 80%, at least about 95% or at least about 99%, where % refers to atomic percent. In the copper seed layer at least some copper is metallic copper in zero oxidation state.

The term “protective metal layer” (e.g., protective cobalt layer) refers to a layer that includes a metal, where the metal may be in zero oxidation state or in an oxidized form (in non-zero oxidation state). For example, protective cobalt layer may include cobalt oxide, or may consist essentially of cobalt oxide. In some embodiments the protective metal layer includes both metal in zero oxidation state and in non-zero oxidation state.

“Metals that are less noble than copper” refer to metals with a lower (more negative) standard electrode potential than copper. For example, cobalt, tin, zinc, and iron have lower standard electrode potentials than copper (referring to reduction to zero oxidation state).

The methods are particularly useful for electroplating on substrates having narrow recessed features with widths of less than about 20 nm, such as less than about 15 nm. The widths of recessed features, as used herein, refer to widths after copper seed layer deposition, unless otherwise noted.

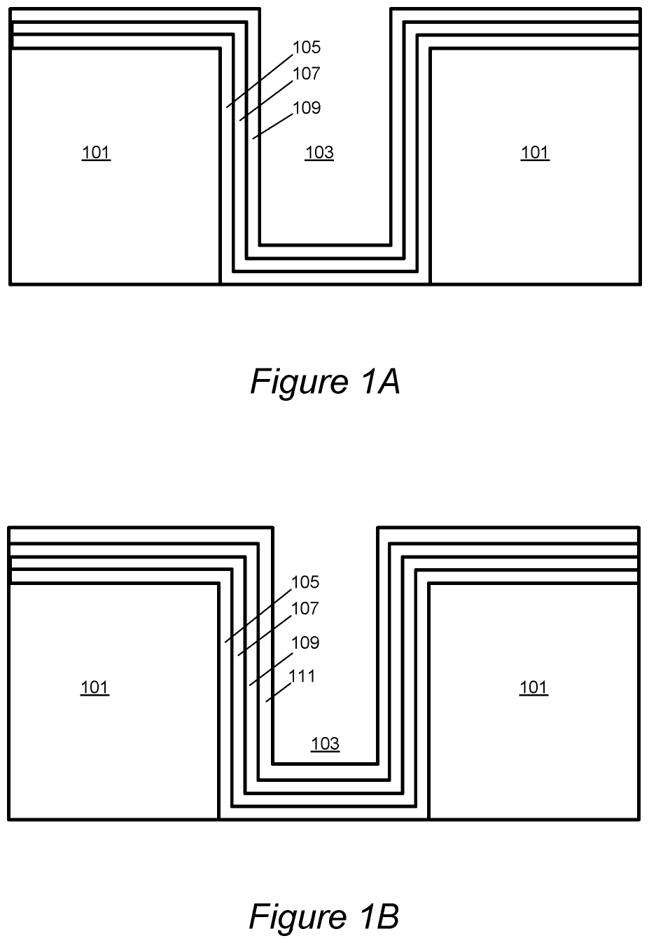

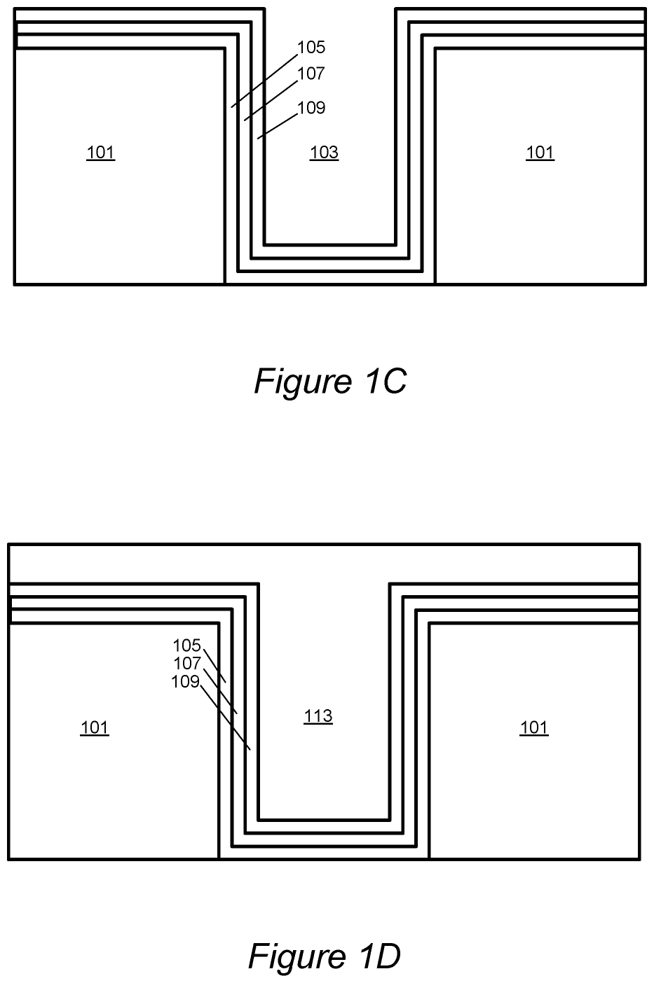

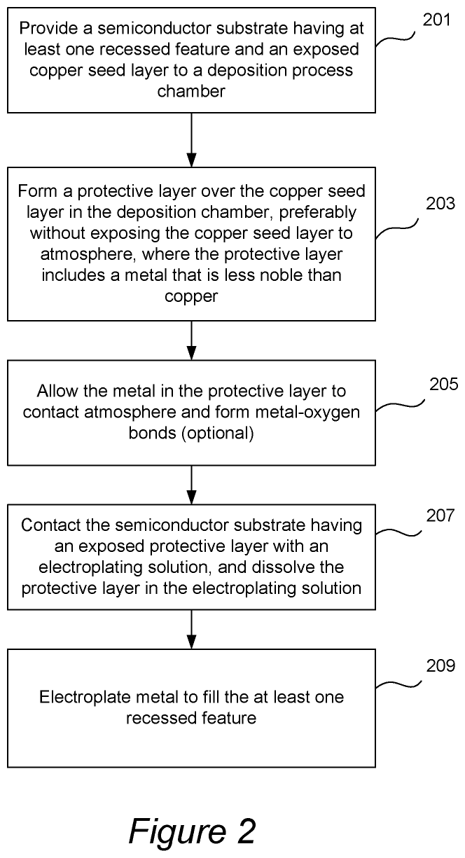

An embodiment of provided methods is illustrated by FIGS. 1A-1D, which shows schematic cross-sectional views of a portion of a semiconductor substrate during processing. The method is further illustrated by FIG. 2 which provides a process flow diagram illustrating for embodiment of the method. Referring to FIG. 2, the process starts in 201 by providing a semiconductor substrate having at least one recessed feature and an exposed copper seed layer to a process chamber. In some embodiments, the substrate is a semiconductor wafer having a plurality of recessed features, such as vias and trenches, formed in a layer of dielectric. A portion of a substrate, according to one embodiment, is shown in FIG. 1A. The substrate includes a dielectric layer 101, with a recessed feature 103 formed in the dielectric layer 101, where the substrate is conformally lined with a stack of layer, including a diffusion barrier layer 105 in contact with the dielectric layer 101, a wetting layer 107 in contact with the diffusion barrier layer 105, and a copper seed layer 109 formed over the wetting layer 107. Such substrate can be obtained by first patterning the dielectric layer 109 to form a recessed feature 103 by photolithographic methods, followed by sequential deposition of a diffusion barrier material (e.g., one or more of TaNx, TiNx, WNx, and WCNx), a wetting layer material (e.g., cobalt), and, finally a copper seed layer material (e.g., pure copper or a copper alloy). The diffusion barrier layer 105 serves to protect the dielectric layer 101 from the diffusion of copper into the dielectric 101. The diffusion barrier material, in some embodiments, is deposited by PVD. For example, TaNx or a TiNx bi-layer can be deposited over the substrate by PVD using a tantalum or titanium sputter target and a nitrogen-containing process gas. Next, after the diffusion barrier material has been deposited, a wetting layer 107 is deposited over the diffusion barrier layer 105. The wetting layer 107 serves to promote adhesion of copper seed material to the diffusion barrier material. In some embodiments, the wetting layer is not used, and the copper seed layer is deposited directly onto the diffusion barrier layer 103. In the illustrated embodiment, the wetting material is cobalt, which can be deposited, for example, by CVD, ALD, or PVD. The copper seed layer 109 is typically deposited by PVD either onto the wetting layer 107 or directly onto the diffusion barrier layer 105 when the wetting layer is not used. The structure shown in FIG. 1A illustrates a substrate in which the copper seed layer 109 is exposed both in the field region, on the sidewalls of the recessed feature, and at the bottom of the recessed feature. In other embodiments the copper seed layer may be exposed only on the portion of the substrate, e.g., at least at the sidewalls of the recessed feature. For example, in some embodiments the bottom of the recessed feature may include an exposed conductive material of an underlying layer (e.g., copper line from a lower metallization layer), with the copper seed layer being removed from the bottom of the recessed feature by resputtering. In other embodiments, copper seed layer in the field region may be covered with a non-conducting material. The thicknesses of the diffusion barrier layer 105, the wetting layer 107 and the copper seed layer 107 can vary depending on the size of a recessed feature 103. In some embodiments each of the layers has a thickness in a range of between about 10-200 Å, more typically between about 10-50 Å, referring to an average thickness at the sidewalls. In some embodiments, the width of the recessed feature after copper seed layer deposition is less than about 20 nm, and the thickness of the copper seed layer is between about 0.5-3 nm, referring to an average thickness at the sidewalls.

After the substrate having an exposed copper seed layer has been formed, the substrate is placed into a deposition process chamber for depositing a protective layer. Preferably, the copper seed layer is not exposed to atmosphere or oxidizing gasses during copper seed layer deposition or after the deposition, as the substrate is transferred to the process chamber configured for deposition of the protective layer without an air break. This is done to prevent formation of copper oxide on the copper seed layer.

Referring to FIG. 2, the protective layer, which includes a metal that is less noble than copper, is deposited in operation 203 over the protective seed layer in a deposition chamber, preferably without exposing the copper seed layer to atmosphere. The protective layer can be deposited by a variety of methods including PVD. CVD, and ALD. Examples of metals that are less noble than copper that can be deposited in this step include cobalt, tin, zinc, and iron. In some embodiments the metals in the protective layer as-deposited are in zero oxidation state. In one embodiment a cobalt metal protective layer is deposited on the substrate by a reaction of a cobalt-containing precursor in a CVD or ALD process. In some embodiments, after the deposition, in operation 205, the substrate is exposed to atmosphere, and the metals in the protective layer are allowed to form metal-oxygen bonds. The metals in the protective layer can be converted to oxides either partially or completely. In some embodiments, at least 90% of the metal in the protective layer is converted to metal oxide. In other embodiments substantially all of the metal in the protective layer is converted to metal oxide. For example, cobalt metal in the protective layer can be oxidized to cobalt oxide upon exposure to atmosphere. In other embodiments, after metal in zero oxidation state has been deposited it is subjected to an oxidizing treatment to form metal oxide in a more controlled environment than atmospheric exposure. For example, the substrate may be exposed to an oxygen-containing reactant, such as O2 or O3, in a process chamber, optionally in a presence of plasma to form metal oxide, such as cobalt oxide.

The structure obtained after formation of the protective layer is shown in FIG. 1B. In the illustrated embodiment, the protective layer 111 is formed conformally over the copper seed layer 109, and covers the copper seed layer 109 in the field region, at the sidewalls of the recessed feature 103, and at the bottom of the recessed feature 103. In some embodiments, the formed protective layer 111 has a thickness of between about 1-20 nm. In narrow features with widths of about 20 nm or less, the protective layer typically has a thickness of less than about 3 nm, such as between about 1-2 nm. In one specific example, a cobalt protective layer with a thickness of between about 1-2 nm is deposited over a copper seed layer having a thickness of between about 2-3 nm. The protective layer residing over the copper seed layer can substantially block contact of the copper seed layer with atmosphere, and prevent or diminish oxidation of the copper seed layer.

Next, in operation 207, the substrate having an exposed protective layer is contacted with an electroplating solution, and the protective layer is dissolved. This step occurs in an electroplating apparatus during initial stages of electroplating. For example, the substrate having an exposed protective layer which includes metal oxides (e.g., cobalt oxide, iron oxide, zinc oxide, or tin oxide) and/or metals in zero oxidation state that are soluble in acids (e.g., cobalt, iron, zinc, or tin) can be contacted with an acidic copper plating solution. The copper plating solution includes a copper salt (e.g., copper sulfate and or copper methanesulfonate) and an acid (e.g., sulfuric and or methansulfuric acid) and optionally additives (e.g., halides, accelerators, suppressors, and levelers) that aid in filling the recessed features. In some embodiments, the substrate is not electrically biased during the initial contact with the electrolyte. For example, the substrate may be cathodically biased about 1 second or less (e.g., 0.1-1 seconds) after initial contact. This method is referred to as cold entry, and is preferred in some embodiments because it does not impede the dissolution of the protective layer. In other embodiments, the substrate may be cathodically biased during the initial contact with the electrolyte. For example, potentiostatic substrate entry is used in some embodiments, where the substrate is kept at a constant potential during the initial exposure to electrolyte. The bias is selected such as not to completely block dissolution of the protective layer. In some embodiments at least 90% of the protective layer is dissolved during the initial contact with the electrolyte. In some embodiments substantially all of the protective layer material is dissolved during this step, and the copper seed layer is exposed. The structure resulting after the protective seed layer dissolution is shown in FIG. 1C. In this illustration, the protective layer 111 is completely removed, and the underlying copper seed layer 109 is now exposed to electrolyte.

In operation 209, metal is electroplated to fill the at least one recessed feature on the semiconductor substrate. For example, the recessed feature may be filled with copper. Operations 207 and 209 are typically performed in one electroplating apparatus, where dissolution of the protective layer 207 immediately precedes filling of the feature. Typically the electrolytes used for dissolution of the protective seed layer and for electrofilling the recessed features with metal, have substantially the same composition. For example, copper is electrodeposited into the recessed feature by contacting the cathodically biased substrate with an electrolyte containing copper salt, an acid, and, optionally, electroplating additives. In some embodiments it is preferable to remove a portion of the electrolyte from the electroplating chamber and replenish the electrolyte with a fresh make-up solution during electroplating, or between electroplating operations on multiple substrates. This bleed-and-feed of electrolyte is useful for reducing concentration of metal ions that entered the electrolyte after dissolution of the protective layer. However, the amount of the metal ions from the protective layer material is usually small, and these ions do not typically cause adverse effects during electrofill. For example, small amounts of cobalt ions may be present in the electrolyte during electrodeposition of copper into the recessed features.

The structure that is formed after electrofill has been completed is shown in FIG. 1D, which shows an electrodeposited metal layer 113 filling the recessed feature and forming an overburden in the field region. The use of a protective layer can substantially reduce the number of defects (such as voids near the sidewalls) or eliminate such defects in semiconductor substrates undergoing Damascene processing. This advantage is particularly pronounced when electroplating is performed in narrow features with widths of less than about 20 nm, or less than about 15 nm.

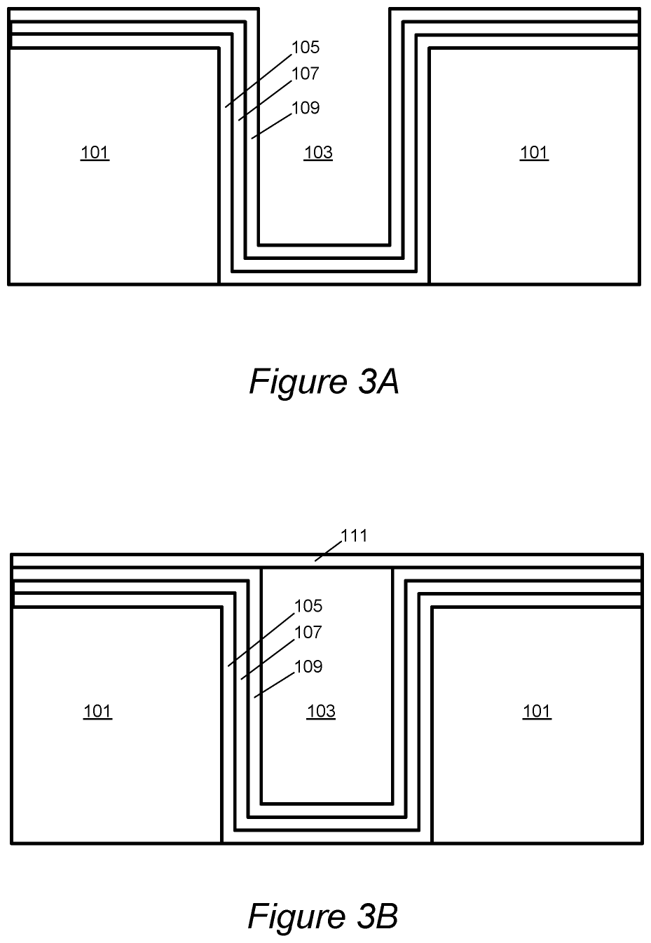

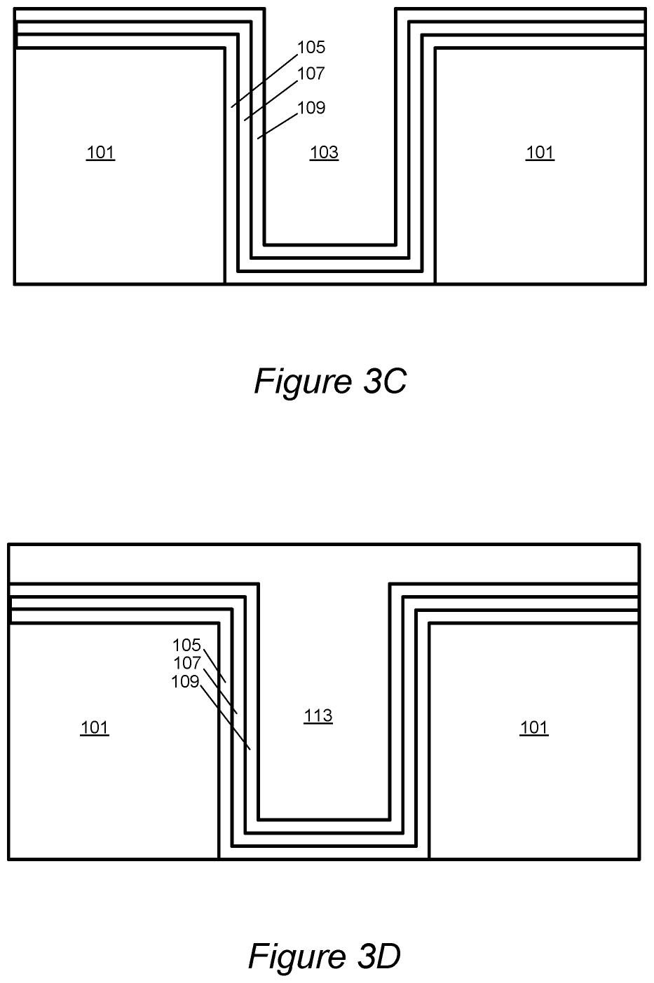

In the embodiment illustrated by FIGS. 1A-1D, the protective layer is deposited conformally such that it coats the copper seed layer at the sidewalls of the recessed feature. In an alternative embodiment, the protective layer may be deposited as a plug that seals off the recessed feature, and thereby prevents the copper seed layer from contacting atmosphere. This embodiment is illustrated in FIGS. 3A-3D. This embodiment is particularly suitable for processing substrate with very narrow recessed features, e.g., features with widths of 5 nm or less (such as about 3 nm or less), because conformal deposition of metals into such narrow features is difficult. The substrate shown in FIG. 3A has a similar structure to the substrate described with reference to FIG. 1A. The substrate is placed into a deposition chamber and a protective layer 111 is formed non-conformally such that it covers the field region and the opening of the recessed feature 103, without covering the sidewalls of the recessed feature, as shown in FIG. 3B. The void is formed in the recessed feature 103, which is sealed off from the atmosphere by the protective layer 111 that covers the opening of the recessed feature. The deposition of the protective layer is preferably conducted such that the copper seed layer is not allowed to contact atmosphere, and, therefore, the void inside the recessed feature is not filled by air. This configuration allows the copper seed layer at the sidewalls to be protected from oxidation. Next, the substrate may be exposed to atmosphere and the metal in the protective layer 111 may react with oxygen to form a metal oxide. This transformation does not affect the copper seed layer at the sidewalls, which remains protected from contact with air.

Next, the substrate is contacted with an electroplating solution, and the protective layer 111 is dissolved, opening up the copper seed layer to the electroplating solution. The resulting structure that no longer has a protective layer is shown in FIG. 3C. Next, metal (e.g., copper) is electroplated into the recessed feature, forming a structure shown in FIG. 3D. The dissolution of the protective layer and electrodeposition of copper can overlap in time.

In some embodiments, the metal of the protective layer is cobalt. Cobalt is less noble than copper, and it can be oxidized in air without substantially affecting the quality of an underlying copper seed layer. Further, cobalt is a suitable metal for a wetting layer in a stack between a diffusion barrier layer and a copper seed layer. Therefore the use of cobalt for the protective layer in stacks that also utilize a cobalt wetting layer contributes to deposition efficiency, as the same methods and/or process chambers can be used for deposition of the wetting layer and the protective layer.

A comparison of the standard equilibrium potentials of Cu/Cu2+ and Co/Co2+ couples reveals that cobalt (Co) has a lower standard equilibrium potential and, therefore, can undergo galvanic corrosion when it is in contact with copper (Cu). The difference in open circuit potential between Cu and Co is about 200 to 300 mV for all pH values within the range of 2 to 10. Cobalt exhibits high corrosion and dissolution rates as well as a strong possibility of galvanic corrosion due to the difference in the corrosion potentials between cobalt and copper in acidic solution. As a result, cobalt film will undergo galvanic corrosion to protect the copper seed layer from corrosion until all cobalt is oxidized.

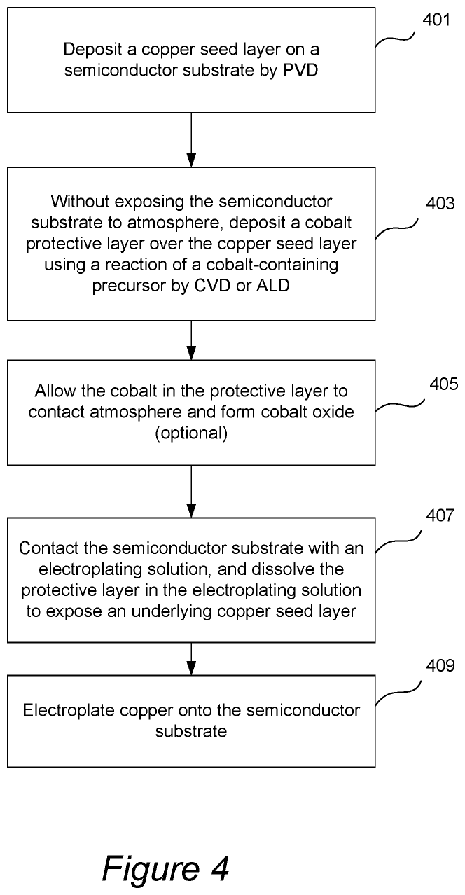

A process diagram for an embodiment that utilizes a cobalt protective layer is shown in FIG. 4. In operation 401 a copper seed layer is deposited onto the substrate by PVD. In some embodiments a cobalt wetting layer is pre-deposited onto a diffusion barrier material prior to copper seed layer deposition, and the copper seed layer is deposited onto cobalt. The deposition is performed in a PVD chamber, without exposing the substrate to atmosphere during or immediately after the deposition. The substrate is placed onto a support in a PVD chamber housing a copper target (or a target made of an appropriate copper alloy), and a process gas, such as argon is introduced into the process chamber. Copper is sputtered onto the substrate such that the copper seed layer coats the substrate, as shown in FIG. 1A. Next, in 403, without exposing the substrate to atmosphere, a cobalt protective layer is deposited over the copper seed layer by reacting a cobalt-containing precursor to form cobalt metal. The deposition may be performed by CVD (where the reaction occurs in bulk in the process chamber) or by ALD (where the reaction occurs on the surface of the substrate). The terms CVD and ALD as used herein are inclusive of both thermal and plasma-assisted depositions. After cobalt has been deposited, in operation 405, the substrate is exposed to atmosphere, resulting in a formation of cobalt oxide in the protective layer. Alternatively the substrate is treated with an oxygen-containing reactant (e.g., with a remote plasma formed in an oxygen-containing gas) in a process chamber to controllably form cobalt oxide. Next, in operation 407 the substrate is contacted with an electroplating solution such that the protective layer (cobalt oxide and cobalt metal, if present) is dissolved, thereby exposing the copper seed layer. In operation 409, copper is electroplated onto the substrate.

Process conditions and deposition methods for deposition of layers in the described methods can vary and can depend on the type of the substrate, size of the recessed features, etc. In some embodiments the copper seed layer and the protective layer are deposited in one tool or a module, which allows for deposition of these layers without exposing the substrate to atmosphere after deposition of copper seed layer and before deposition of the protective layer.

Cobalt may be deposited by CVD, ALD, or PVD methods. In some embodiments cobalt is deposited conformally in the feature by ALD or CVD methods. In a CVD method, the substrate is exposed to a suitable cobalt-containing precursor and a reducing agent to form a cobalt layer on the substrate. The temperature may be between about 70° C. and about 400° C., or between about 80° C. and about 200° C. In some embodiments, the temperature may be between about 70° C. and about 200° C., or between about 100° C. and about 120° C. The chamber pressure may be about 0.1 Torr to about 10 Torr, or between about 1 Torr and about 5 Torr. In some embodiments, the chamber pressure may be between about 0.5 Torr and about 10 Torr, or between about 1 Torr and about 3 Torr. In various embodiments, the suitable cobalt-containing precursor and/or reducing agent are introduced into the chamber using a carrier gas, such as argon (Ar), nitrogen (N2), or carbon monoxide (CO). In some embodiments, the cobalt-containing precursor is introduced to the chamber using argon as a carrier gas. The flow rate of the carrier gas may be between about 10 sccm and about 300 sccm, or between about 10 sccm and about 50 sccm. In some embodiments, the flow rate of the carrier gas may be between about 10 sccm and about 100 sccm, or between about 10 sccm and about 30 sccm. The reducing agent may be any suitable reactant for reducing the selected cobalt-containing precursor. In various embodiments, the reducing agent is hydrogen (H2). The reducing agent may be introduced at a flow rate between about 100 sccm and about 5000 sccm, or between about 2000 sccm and about 5000 sccm. It will be understood that, depending on the particular deposition chamber, flow rates outside of the ranges provided throughout this disclosure may be used.

In an ALD method, the substrate may be exposed in cycles such that the substrate is first exposed to a pulse of a suitable cobalt-containing precursor, then the precursor is purged, then the substrate is exposed to a pulse of a reducing agent, and then the reducing agent is purged, and such cycles may be repeated until a desired thickness of cobalt is formed on the substrate. For a deposition process by ALD, the temperature may be between about 70° C. and about 400° C., or between about 100° C. and about 200° C. In some embodiments, the temperature may be between about 70° C. and about 200° C., or between about 100° C. and about 120° C. The pressure may be between about 1 Torr and about 20 Torr, or between about 8 Torr and about 15 Torr. In various embodiments, the cobalt-containing precursor and/or reducing agent are introduced into the chamber using a carrier gas, such as Ar, N2, or CO. In some embodiments, the cobalt-containing precursor is introduced to the chamber using Ar as a carrier gas. The flow rate of the carrier gas may be between about 10 sccm and about 300 sccm, or between about 10 sccm and about 100 sccm. In some embodiments, the flow rate of the carrier gas may be between about 50 sccm and about 100 sccm. The reducing agent may be any suitable reactant for reducing the selected cobalt-containing precursor. In various embodiments, the reducing agent is H2. The reducing agent may be introduced at a flow rate between about 100 sccm and about 5000 sccm, or between about 2000 sccm and about 5000 sccm. The time when operation 206 is terminated depends on the size of the feature.

Examples of cobalt-containing precursors include dicarbonyl cyclopentadienyl cobalt (I), cobalt carbonyl, various cobalt amidinate precursors, cobalt diazadienyl complexes, cobalt amidinate/guanidinate precursors, and combinations thereof. Suitable cobalt-containing precursors may include a cobalt center with organic groups and/or carbonyl groups, where organic groups include alkyls, such as methyl, ethyl, propyl, butyl, pentyl, hexyl, heptyl, and octyl, which may be straight or branched hydrocarbon chains. In some embodiments, the organometallic compound has a substituted or unsubstituted allyl ligand. In some embodiments, the allyl ligand is unsubstituted.

In some embodiments the organometallic cobalt compound has the following structure:

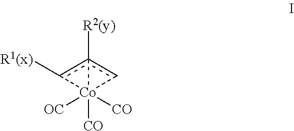

where R1 is C1-C8-alkyl, R2 is C1-C8 alkyl, x is zero, 1 or 2; and y is zero or 1.

In some embodiments R1 is a C2-C8-alkyl, R2 is independently C2-C8 alkyl.

The term “alkyl” as used herein refers to saturated hydrocarbon chain of 1 to 8 atoms in length, such as methyl, ethyl, propyl, butyl, pentyl, hexyl, heptyl, and octyl. The term “alkyl” includes both straight and branched hydrocarbon chains. Thus, the term propyl includes both n-propyl and isopropyl. The term butyl includes both n-butyl, sec-butyl, iso-butyl, and tert-butyl.

In some embodiments x is 0 and y is 1. An example of an organometallic compound in accordance with this embodiment is shown below:

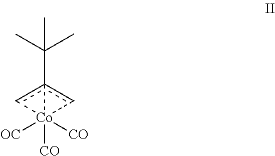

Certain described compounds are available from SAFC-Hitech of Haverhill, Mass., in conjunction with corresponding deposition apparatuses available from Lam Research Inc., of Fremont, Calif. After the cobalt protective layer has been formed, the substrate is exposed to atmosphere and is transferred to an electroplating apparatus.

Electrodeposition of metals is performed in an electroplating apparatus, where the apparatus includes a plating chamber configured for holding an electrolyte and an anode. The apparatus further includes a substrate holder, which may be configured to rotate the substrate during electroplating, and typically includes a plurality of electrical contacts in electrical communication with the power supply. The apparatus is configured to cathodically bias the substrate during electrodeposition. The plating chamber can include an inlet and an outlet for adding and removing electrolyte, for example to provide bleed-and-feed replenishment of electrolyte. The electrolyte is an aqueous solution that includes metal ions, and, typically an acid.

Electrodeposition of copper to fill the recessed features can be performed in any suitable electrolyte that includes copper ions, and, preferably an acid (e.g., sulfuric acid, methanesulfonic acid or a mixture of these acids). The electrolyte may further include additives that promote bottom-up fill, such as halide ions, suppressors, accelerators, and levelers. In some embodiments it is preferable to electroplate copper using an electrolyte having low concentration of copper ions. In one aspect, the embodiments herein provide a method of electroplating copper into damascene features, including receiving a substrate with a copper seed layer covered by a protective cobalt layer; immersing the substrate in an aqueous low copper acid-containing electrolyte having less than about 10 g/L copper ions, and an acidic pH; and electrically biasing the substrate. In some embodiments the substrate is cathodically biased after the substrate first contacts the electrolyte. The protective cobalt layer dissolves in an acidic electrolyte, and copper is electroplated onto the copper seed layer.

The low-copper electrolyte in some embodiments includes at least one suppressor compound. While not wishing to be bound to any theory or mechanism of action, it is believed that suppressors (either alone or in combination with other bath additives) are surface-kinetic polarizing compounds that lead to a significant increase in the voltage drop across the substrate-electrolyte interface, especially when present in combination with a surface chemisorbing halide (e.g., chloride or bromide). The halide may act as a bridge between the suppressor molecules and the wafer surface. The suppressor both (1) increases the local polarization of the substrate surface at regions where the suppressor is present relative to regions where the suppressor is absent, and (2) increases the polarization of the substrate surface generally. The increased polarization (local and/or general) corresponds to increased resistivity/impedance and therefore slower plating at a particular applied potential.

It is believed that suppressors are not incorporated into the deposited film, though they may slowly degrade over time. Suppressors are often relatively large molecules, and in many instances they are polymeric in nature (e.g., polyethylene oxide, polypropylene oxide, polyethylene glycol, polypropylene glycol, etc). Other examples of suppressors include polyethylene and polypropylene oxides with S- and/or N-containing functional groups, block polymers of polyethylene oxide and polypropylene oxides, etc. The suppressors can have linear chain structures or branch structures. It is common that suppressor molecules with various molecular weights co-exist in a commercial suppressor solution. Due in part to suppressors' large size, the diffusion of these compounds into a recessed feature is relatively slow.

In some embodiments the method involves electroplating copper into the features at a current density of about 3 mA/cm2 or less. In certain embodiments (e.g., when low copper concentrations are used), the electrolyte may include between about 2-15 g/L acid, or between about 5-10 g/L acid. The pH of the electrolyte may be between about 0.2-2 in some implementations. The electrolyte may also include between about 10-500 milligrams per liter active organic additives. In some implementations, the active organic additives may include one or more accelerator compound. The concentration of accelerator may be less than about 20 milligrams per liter, or less than about 10 milligrams per liter. In certain cases, the active organic additives include one or more leveler compound. In some implementations, the electrolyte includes less than about 5 g/L copper ions. Further, the electrolyte may include between about 10-150 milligrams per liter halide ions. When immersing the substrate in certain embodiments, the substrate may be immersed at an angle relative to the surface of the electrolyte and then oriented horizontally. The electroplating operation may include electroplating copper during a first plating phase to fill the substrate features with copper at a first deposition rate; and electroplating copper during a second plating phase to deposit an overburden layer of copper on the substrate at a second deposition rate that is higher than the first deposition rate. The method of electroplating may also include performing a post-plating treatment on the substrate. In certain implementations, the post-plating treatment includes rinsing and/or planarizing the substrate.

### Experimental Results

Copper was electrodeposited onto wafer substrates having a plurality trenches, with widths of about 10 nm after diffusion barrier deposition and before copper seed deposition. [The trenches were formed in a dielectric layer, where the dielectric was lined with a stack containing a TaN diffusion barrier layer (3 nm thick PVD-deposited TaN), cobalt wetting layer (1 nm thick CVD-deposited cobalt metal), and a copper seed layer (2-3 nm thick CuMn alloy or Cu deposited by PVD).

In Example 2, 3, and 4, a 1 nm thick layer of cobalt was deposited over copper seed layer by CVD without exposing copper seed layer to atmosphere. The substrate was then exposed to atmosphere and cobalt was allowed to oxidize.

In Example 5, 6, and 7 a 2 nm thick layer of cobalt was deposited over copper seed layer by CVD without exposing copper seed layer to atmosphere. The substrate was then exposed to atmosphere and cobalt was allowed to oxidize.

Electrodeposition was conducted in an electrolyte containing 2 g/L copper ions, 10 g/L sulfuric acid, 50 ppm chloride ions, accelerator, suppressor, and a leveler

Example 1 (comparative). Electroplating was performed on a substrate that did not have a protective cobalt layer, and contained an exposed copper seed layer (CuMn alloy). The substrate was immersed into the electrolyte under potentiostatic entry conditions, and the recessed features were filled at a current density of 2.6 mA/cm2. Multiple voids were observed on the microscopic images of the fill.

Example 2 (1 nm cobalt protective layer, potentiostatic entry). Electroplating was performed on a substrate that had a 1 nm thick protective cobalt layer formed over the copper seed layer (Cu). The substrate was immersed into the electrolyte under potentiostatic entry conditions, and the recessed features were filled at a current density of 2.0 mA/cm2. A significant reduction in the number of voids compared to Example 1 was observed.

Example 3 (1 nm cobalt protective layer, open circuit potential (OCP) entry). Electroplating was performed on a substrate that had a 1 nm thick protective cobalt layer formed over the copper seed layer (Cu). The substrate was immersed into the electrolyte under OCP conditions (without biasing the substrate), the substrate was biased after 1 second, and the recessed features were filled at a current density of 2.0 mA/cm2. The quality of the fill was similar to Example 2.

Example 4 (1 nm cobalt protective layer, open circuit potential (OCP) entry). Electroplating was performed on a substrate that had a 1 nm thick protective cobalt layer formed over the copper seed layer (Cu). The substrate was immersed into the electrolyte under OCP conditions. The substrate was biased after 2 seconds, and the recessed features were filled at a current density of 2.0 mA/cm2. Multiple voids were observed on the microscopic images of the fill. The quality of the fill was worse than in Example 2 and Example 3.

Example 5 (2 nm cobalt protective layer, potentiostatic entry). Electroplating was performed on a substrate that had a 2 nm thick protective cobalt layer formed over the copper seed layer (Cu). The substrate was immersed into the electrolyte under potentiostatic entry conditions, and the recessed features were filled at a current density of 2.0 mA/cm2. A significant reduction in the number of voids compared to Example 1 was observed. The quality of the fill was better than in Example 2.

Example 6 (2 nm cobalt protective layer, open circuit potential (OCP) entry). Electroplating was performed on a substrate that had a 2 nm thick protective cobalt layer formed over the copper seed layer (Cu). The substrate was immersed into the electrolyte under OCP conditions. The substrate was biased after 1 second, and the recessed features were filled at a current density of 2.0 mA/cm2. The quality of the fill was similar to Example 5.

Example 7 (2 nm cobalt protective layer, open circuit potential (OCP) entry). Electroplating was performed on a substrate that had a 2 nm thick protective cobalt layer formed over the copper seed layer (Cu). The substrate was immersed into the electrolyte under OCP conditions. The substrate was biased after 2 seconds, and the recessed features were filled at a current density of 2.0 mA/cm2. Multiple voids were observed on the microscopic images of the fill, but the number of voids was less than in Example 1. The quality of the fill was worse than in Example 5 and Example 6.

Improvement in copper fill near the sidewalls was clearly observed in examples that employed a cobalt protective layer. The improvement was greater when thicker cobalt layer (2 nm) was used. Electroplating using potentiostatic entry and OCP entry (1 second) produced similarly good results for substrates that employed a cobalt protective layer. Longer OCP time (2 seconds) degraded sidewall integrity.

### Apparatus

Various steps of provided methods can be implemented in PVD, CVD, ALD, and electrodeposition apparatuses. For example, PVD deposition of copper seed layer can be performed in a PVD apparatus having a process chamber configured to hold a copper target and a substrate support. Cobalt wetting layer and cobalt protective layer can be deposited in a CVD or an ALD apparatus such as an Altus® tool available from Lam Research Corporation. Inc. Electrodeposition of copper can be carried out in a Sabre® tool available from Lam Research Corporation, Inc. In some embodiments deposition of copper seed layer and deposition of a protective layer are performed in a single module that is configured for performing PVD and CVD without exposing the substrate to atmosphere between these depositions. For example, the apparatus may include a PVD process chamber configured for deposition of copper and a CVD or ALD process chamber configured for deposition of cobalt, where the apparatus allow the transfer of the substrate between the copper deposition chamber and the cobalt deposition chamber without an air break.

In some embodiments, an apparatus is provided, where the apparatus includes one or more process chambers (e.g., one or more of PVD, CVD, ALD, or electroplating process chambers) and a controller comprising program instructions for performing any of the methods provided herein. For example, the apparatus may include a PVD, CVD and/or ALD process chamber and a controller comprising program instructions for causing deposition of a protective layer comprising a metal that is less noble than copper over a copper seed layer on the semiconductor substrate. For example the controller may include instructions for causing deposition of cobalt by CVD or ALD.

Deposition of a protective layer can be performed in any of the PVD, CVD or ALD process chambers, where each may optionally include equipment for generating a plasma. Such a chamber may take many forms, and may be part of an apparatus that includes one or more chambers or reactors (sometimes including multiple stations) that may each house one or more substrate or wafers and may be configured to perform various substrate processing operations. The one or more chambers may maintain the substrate in a defined position or positions (with or without motion within that position, e.g., rotation, vibration, or other agitation). In one implementation, a substrate undergoing film deposition may be transferred from one station to another within a chamber during the process. In other implementations, the substrate may be transferred from chamber to chamber within the apparatus to perform different operations, such as PVD operations and CVD operations. While in process, each substrate may be held in place by a pedestal, substrate chuck, and/or other substrate-holding apparatus. For certain operations in which the substrate is to be heated, the apparatus may include a heater, such as a heating plate.

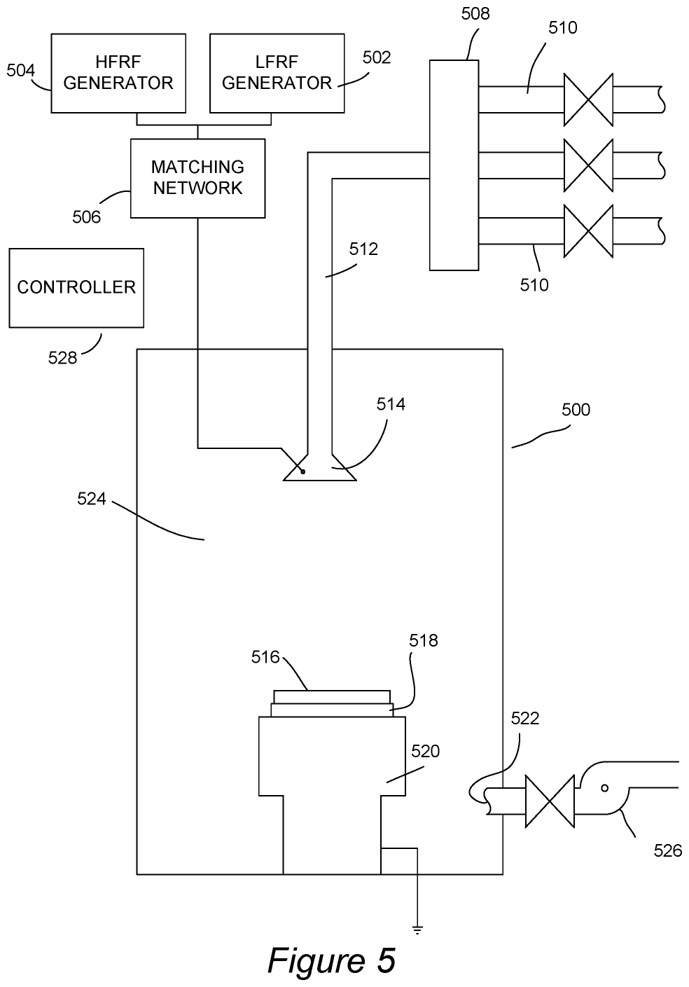

FIG. 5 provides a simple block diagram depicting various reactor components arranged for implementing CVD deposition of a protective layer, according to one of the embodiments. As shown, a reactor 500 includes a process chamber 524 that encloses other components of the reactor and is also configured to contain a plasma generated by a capacitive-discharge type system including a showerhead 514 working in conjunction with a grounded heater block 520. While plasma is not necessarily used during protective layer deposition, in some embodiments, CVD of the protective layer may be conducted in a process chamber equipped with a plasma generator, because plasma treatment may be used for substrate pre-treatment or post-treatment. In the depicted process chamber a high frequency (HF) radio frequency (RF) generator 504 and a low frequency (LF) RF generator 502 may be connected to a matching network 506 and to the showerhead 514. The power and frequency supplied by matching network 506 may be sufficient to generate a plasma from process gases supplied to the process chamber 524. For example, the matching network 506 may provide 100 W to 1000 W of power. In some examples, the matching network 506 may provide. In a typical process, the HFRF component may generally be between 1 MHz to 100 MHz, e.g., 13.56 MHz. In operations where there is an LF component, the LF component may be from less than about 1 MHz. e.g., 100 kHz. In some implementations, cobalt CVD is performed without using a plasma.

Within the reactor, a pedestal 518 may support a substrate 516. The pedestal 518 may include a chuck, a fork, or lift pins (not shown) to hold and transfer the substrate during and between the deposition and/or plasma treatment reactions. The chuck may be an electrostatic chuck, a mechanical chuck, or various other types of chuck as are available for use in the industry and/or for research.

Various process gases may be introduced via inlet 512. Multiple source gas lines 510 are connected to manifold 508. The gases may be premixed or not. Appropriate valving and mass flow control mechanisms may be employed to ensure that the correct process gases are delivered during the deposition and plasma treatment phases of the process. In the case where a chemical precursor(s) is delivered in liquid form, liquid flow control mechanisms may be employed. Such liquids may then be vaporized and mixed with process gases during transportation in a manifold heated above the vaporization point of the chemical precursor supplied in liquid form before reaching the deposition chamber.

Process gases, such as a cobalt-containing precursor or nitrogen-containing gas, may exit chamber 524 via an outlet 522. A vacuum pump, e.g., a one or two stage mechanical dry pump and/or turbomolecular pump 540, may be used to draw process gases out of the process chamber 524 and to maintain a suitably low pressure within the process chamber 524 by using a closed-loop-controlled flow restriction device, such as a throttle valve or a pendulum valve.

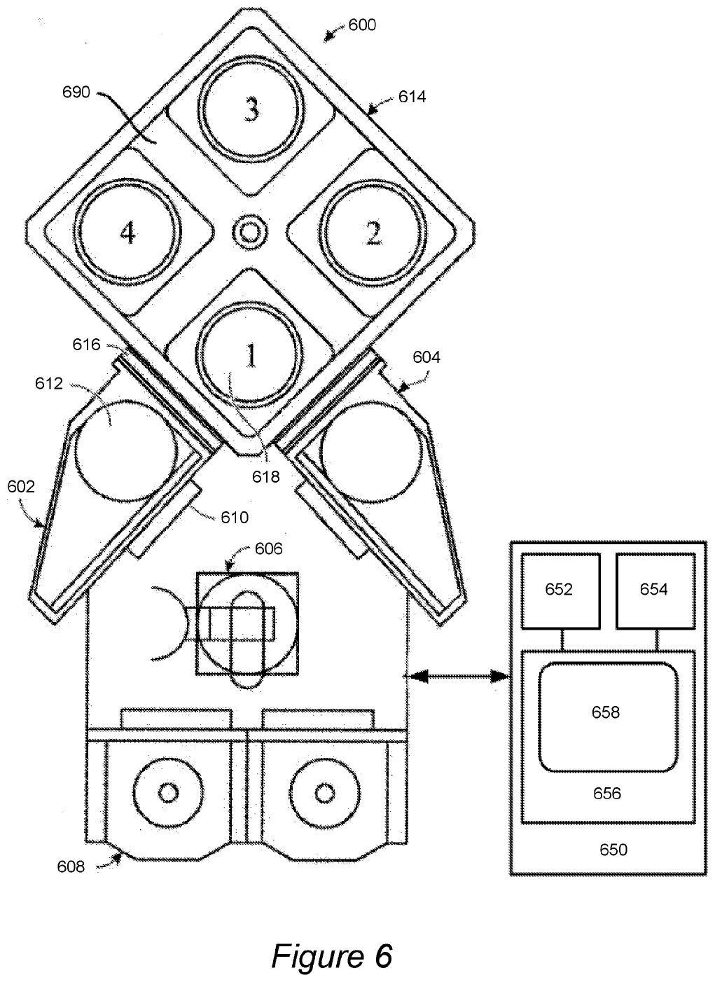

As discussed above, the techniques for deposition discussed herein may be implemented on a multi-station or single station tool. FIG. 6 is a schematic illustration of an example of such a tool. In specific implementations, tools for processing 200 mm, 300, or 450 mm wafers may be used. In various implementations, the substrates may be indexed after every deposition and/or post-deposition treatment, or may be indexed after etching steps if the etching chambers or stations are also part of the same tool, or multiple depositions and treatments may be conducted at a single station before indexing the substrate.

In some embodiments, an apparatus may be provided that is configured to perform the techniques described herein. A suitable apparatus may include hardware for performing various process operations as well as a system controller 530 having instructions for controlling process operations in accordance with the disclosed embodiments. The system controller 530 will typically include one or more memory devices and one or more processors communicatively connected with various process control equipment, e.g., valves, RF generators, substrate handling systems, etc., and configured to execute the instructions so that the apparatus will perform a technique in accordance with the disclosed embodiments. Machine-readable media containing instructions for controlling process operations in accordance with the present disclosure may be coupled to the system controller 530. The controller 530 may be communicatively connected with various hardware devices, e.g., mass flow controllers, valves, RF generators, vacuum pumps, etc. to facilitate control of the various process parameters that are associated with the deposition operations as described herein.

In some embodiments, a system controller 530 may control all of the activities of the reactor 500. The system controller 530 may execute system control software stored in a mass storage device, loaded into a memory device, and executed on a processor. The system control software may include instructions for controlling the timing of gas flows, substrate movement, RF generator activation, etc., as well as instructions for controlling the mixture of gases, the chamber and/or station pressure, the chamber and/or station temperature, the substrate temperature, the target power levels, the RF power levels, the substrate pedestal, chuck, and/or susceptor position, and other parameters of a particular process performed by the reactor apparatus 500. For example, the software may include instructions or code for controlling the flow rate of a cobalt-containing precursor, the flow rate of a reducing agent, the flow rate of a nitrogen-containing gas, and exposure times for each of the above described flow chemistries. The system control software may be configured in any suitable way. For example, various process tool component subroutines or control objects may be written to control operation of the process tool components necessary to carry out various process tool processes. The system control software may be coded in any suitable computer readable programming language.

The system controller 530 may typically include one or more memory devices and one or more processors configured to execute the instructions so that the apparatus will perform a technique in accordance with the present disclosure. Machine-readable media containing instructions for controlling process operations in accordance with disclosed embodiments may be coupled to the system controller 530.

As described above, one or more process stations may be included in a multi-station processing tool. FIG. 6 shows a schematic view of an embodiment of a multi-station processing tool 600 with an inbound load lock 602 and an outbound load lock 604, either or both of which may comprise a remote plasma source. A robot 606, at atmospheric pressure, is configured to move substrates from a cassette loaded through a pod 608 into inbound load lock 602 via an atmospheric port 610. A substrate is placed by the robot 606 on a pedestal 612 in the inbound load lock 602, the atmospheric port 610 is closed, and the load lock is pumped down. Where the inbound load lock 602 comprises a remote plasma source, the substrate may be exposed to a remote plasma treatment in the load lock prior to being introduced into a processing chamber 614. Further, the substrate also may be heated in the inbound load lock 602 as well, for example, to remove moisture and adsorbed gases. Next, a chamber transport port 616 to processing chamber 614 is opened, and another robot (not shown) places the substrate into the reactor on a pedestal of a first station shown in the reactor for processing. While the embodiment depicted in FIG. 6 includes load locks, it will be appreciated that, in some embodiments, direct entry of a substrate into a process station may be provided.

The depicted processing chamber 614 comprises four process stations, numbered from 1 to 6 in the embodiment shown in FIG. 6. Each station has a heated pedestal (shown at 618 for station 1), and gas line inlets. Some stations may include similar components to those described above with respect to FIG. 5. It will be appreciated that in some embodiments, each process station may have different or multiple purposes. For example, in some embodiments, a process station may be switchable between an ALD and CVD process mode. Additionally or alternatively, in some embodiments, processing chamber 614 may include one or more matched pairs of ALD and CVD process stations. In some embodiments, the processing chamber 614 may include CVD and PVD stations. In some embodiments features may be coated with copper seed layer by PVD in one station (such as station 1). The substrate may then be transferred to a second station (such as station 2) within the same chamber 614, or to a station in a different chamber, without an air break where the substrate is exposed to a cobalt-containing precursor and a reducing agent to deposit protective cobalt layer by CVD or ALD.

In some embodiments, after the substrate undergoes thermal deposition of cobalt, the substrate is transferred to a different chamber, which may also include various stations. While the depicted processing chamber 614 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 6 depicts an embodiment of a wafer handling system 609 for transferring wafers within processing chamber 614. In some embodiments, wafer handling system 609 may transfer wafers between various process stations and/or between a process station and a load lock. It will be appreciated that any suitable wafer handling system may be employed. Non-limiting examples include wafer carousels and wafer handling robots. FIG. 6 also depicts an embodiment of a system controller 650 employed to control process conditions and hardware states of process tool 600. System controller 650 may include one or more memory devices 656, one or more mass storage devices 654, and one or more processors 652. Processor 652 may include a CPU or computer, analog, and/or digital input/output connections, stepper motor controller boards, etc.

In some embodiments, the controller 650 controls all of the activities of process tool 600. The controller 650 executes system control software 658 stored in mass storage device 654, loaded into memory device 656, and executed on processor 652. Alternatively, the control logic may be hard coded in the controller 650. Applications Specific Integrated Circuits. Programmable Logic Devices (e.g., field-programmable gate arrays, or FPGAs) and the like may be used for these purposes. In the following discussion, wherever “software” or “code” is used, functionally comparable hard coded logic may be used in its place. System control software 658 may include instructions for controlling the timing, mixture of gases, amount of sub-saturated gas flow, chamber and/or station pressure, chamber and/or station temperature, wafer temperature, target power levels, RF power levels, substrate pedestal, chuck and/or susceptor position, and other parameters of a particular process performed by process tool 600. System control software 658 may be configured in any suitable way. For example, various process tool component subroutines or control objects may be written to control operation of the process tool components necessary to carry out various process tool processes. System control software 658 may be coded in any suitable computer readable programming language.

In some embodiments, system control software 658 may include input/output control (IOC) sequencing instructions for controlling the various parameters described above. Other computer software and/or programs stored on mass storage device 654 and/or memory device 656 associated with the controller 650 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 618 and to control the spacing between the substrate and other parts of process tool 600.

A process gas control program may include code for controlling gas composition (e.g., cobalt-containing precursor, reducing agent, and nitrogen-containing gas as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

In some implementations, a controller 650 is part of a system, which may be part of the above-described examples. Such systems can comprise semiconductor processing equipment, including a processing tool or tools, chamber or chambers such as chamber 614, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 650, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller 650 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller 650 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer. For example, parameters may include cobalt-containing precursor gas flow, reducing agent gas flow, carrier gas flow, nitrogen-containing gas flow, plasma power and frequency, pedestal temperature, station or chamber pressure and/or temperature, and others.

The controller 650, in some implementations, may be a part of or coupled to a computer that is integrated with, coupled to the system, otherwise networked to the system, or a combination thereof. For example, the controller 650 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller 650 receives instructions in the form of data, which specify parameters for each of the processing steps to be performed during one or more operations. It should be understood that the parameters may be specific to the type of process to be performed and the type of tool that the controller 650 is configured to interface with or control. Thus as described above, the controller 650 may be distributed, such as by comprising one or more discrete controllers that are networked together and working towards a common purpose, such as the processes and controls described herein. An example of a distributed controller 650 for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller 650 might communicate with one or more of other tool circuits or modules, other tool components, cluster tools such as tool 600, other tool interfaces, adjacent tools, neighboring tools, tools located throughout a factory, a main computer, another controller 650, or tools used in material transport that bring containers of wafers to and from tool locations and/or load ports in a semiconductor manufacturing factory.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with the controller 650. The user interface may include a display screen, graphical software displays of the apparatus and/or process conditions, and user input devices such as pointing devices, keyboards, touch screens, microphones, etc.

In some embodiments, parameters adjusted by the controller 650 may relate to process conditions. Non-limiting examples include process gas composition and flow rates, temperature, pressure, plasma conditions (such as RF bias power levels), pressure, temperature, etc. These parameters may be provided to the user in the form of a recipe, which may be entered utilizing the user interface.

Signals for monitoring the process may be provided by analog and/or digital input connections of the controller 650 from various process tool sensors. The signals for controlling the process may be output on the analog and digital output connections of process tool 600. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

The controller 650 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The controller will typically include one or more memory devices and one or more processors configured to execute the instructions so that the apparatus will perform a method in accordance with the present embodiments. Machine-readable media containing instructions for controlling process operations in accordance with the present embodiments may be coupled to the controller.

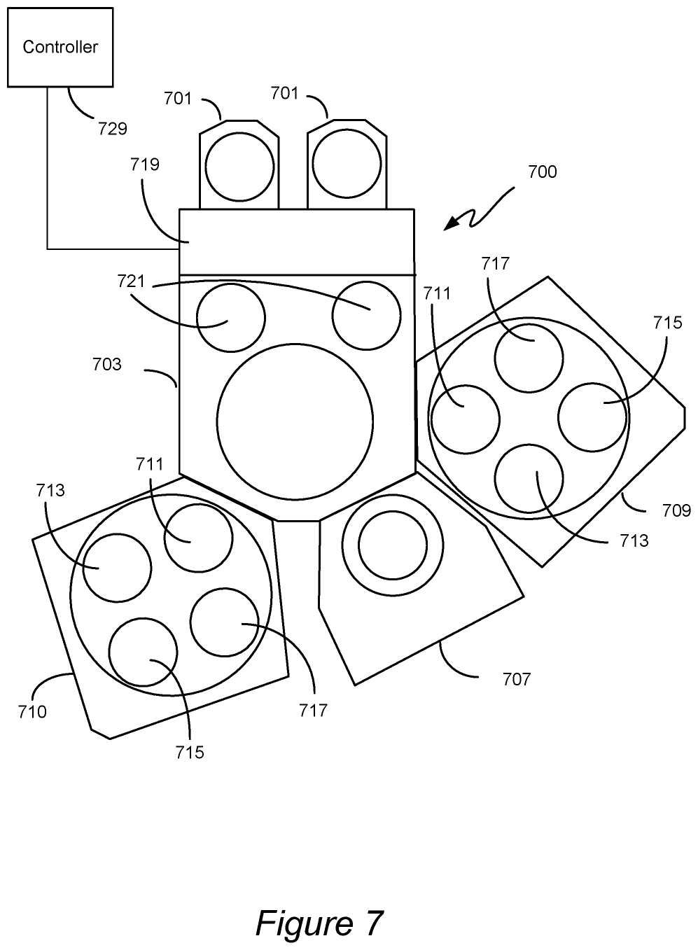

FIG. 7 is a block diagram of a processing system suitable for conducting film deposition processes in accordance with certain embodiments. For example, the system is suitable for deposition of the protective layer and one or more of the deposition of a copper seed layer, wetting layer, and diffusion barrier layer. In some embodiments all of these layers are deposited in the depicted system. The system 700 includes a transfer module 703. The transfer module 703 provides a clean, pressurized environment to minimize risk of contamination of substrates being processed as they are moved between various reactor modules. Mounted on the transfer module 703 are two multi-station reactors 709 and 710, each capable of performing atomic layer deposition (ALD) and/or chemical vapor deposition (CVD) according to certain embodiments. In some embodiments, the processing system further includes a reactor capable of performing PVD. Reactors 709 and 710 may include multiple stations 711, 713, 715, and 717 that may sequentially or non-sequentially perform operations in accordance with disclosed embodiments. The stations may include a heated pedestal or substrate support, one or more gas inlets or showerhead or dispersion plate.

Also mounted on the transfer module 703 may be one or more single or multi-station modules 707 capable of performing plasma or chemical (non-plasma) pre-cleans, or any other processes described in relation to the disclosed methods. The module 707 may in some cases be used for various treatments to, for example, prepare a substrate for a deposition process. The module 707 may also be designed/configured to perform various other processes such as etching or polishing. The system 700 also includes one or more wafer source modules 701, where wafers are stored before and after processing. An atmospheric robot (not shown) in the atmospheric transfer chamber 719 may first remove wafers from the source modules 701 to loadlocks 721. A wafer transfer device (generally a robot arm unit) in the transfer module 703 moves the wafers from loadlocks 721 to and among the modules mounted on the transfer module 703.

In various embodiments, a system controller 729 is employed to control process conditions during deposition. The controller 729 will typically include one or more memory devices and one or more processors. A processor may include a CPU or computer, analog and/or digital input/output connections, stepper motor controller boards, etc.

The controller 729 may control all of the activities of the deposition apparatus and may be configured similarly to the controller 650.

The apparatus/process described herein may be used in conjunction with lithographic patterning tools or processes, for example, for the fabrication or manufacture of semiconductor devices, displays. LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

1. A method of processing a semiconductor substrate, the method comprising:
(a) providing a semiconductor substrate, wherein the provided semiconductor substrate has at least one recessed feature and comprises an exposed copper seed layer at least on the sidewalls of the at least one recessed feature; and
(b) forming a protective layer over the copper seed layer, wherein the protective layer comprises a metal that is less noble than copper.

2. The method of claim 1, wherein the protective layer comprises a metal selected from the group consisting of cobalt, tin, zinc, and iron.

3. The method of claim 1, wherein the protective layer is a cobalt layer.

4. The method of claim 1, wherein (b) comprises forming a cobalt protective layer using chemical vapor deposition (CVD) or atomic layer deposition (ALD).

5. The method of claim 1, wherein (b) comprises forming a cobalt protective layer using physical vapor deposition (PVD).

6. The method of claim 1, wherein (a) comprises depositing the copper seed layer, and (b) comprises depositing a cobalt protective layer, such that the substrate is not exposed to atmosphere after the copper seed layer has been deposited and before the cobalt protective layer is deposited.

7. The method of claim 6, wherein the copper seed layer is deposited by PVD, and the cobalt protective layer is deposited by CVD.

8. The method of claim 1, wherein the protective layer is deposited conformally and covers the copper seed layer at the sidewalls of the at least one recessed feature.

9. The method of claim 1, wherein the protective layer is deposited in (b) over a field region of the semiconductor substrate such that it covers an opening of the at least one recessed feature and thereby prevents the copper seed layer on the sidewalls of the at least one recessed feature from contacting atmosphere.

10. The method of claim 1, further comprising, after (b), exposing the semiconductor substrate to atmosphere, and electrodepositing copper into the at least one recessed feature, wherein the protective layer is substantially dissolved during the electrodeposition of copper.

11. The method of claim 10, wherein the protective layer deposited in (b) is a cobalt protective layer, and wherein cobalt is oxidized to form cobalt-oxygen bonds after exposure to the atmosphere.

12. The method of claim 1, wherein the thickness of the protective layer deposited in (b) is between about 10-50 Å.

13. The method of claim 1, wherein the thickness of the protective layer deposited in (b) is between about 10-20 Å, and the thickness of the copper seed layer is between about 20-30 Å at the sidewalls of the at least one recessed feature.

14. The method of claim 1, wherein the semiconductor substrate provided in (a) further comprises a cobalt adhesion layer underlying the copper seed layer, and a diffusion barrier layer underlying the cobalt adhesion layer.

15. The method of claim 1, wherein the at least one recessed feature has a width of about 20 nm or less.

16. A method of electrodepositing copper into a recessed feature on a semiconductor substrate, the method comprising:
(a) providing a semiconductor substrate having at least one recessed feature lined with a copper seed layer, wherein the semiconductor substrate comprises an exposed protective layer overlying the copper seed layer, wherein the protective seed layer comprises a metal that is less noble than copper; and
(b) contacting the semiconductor substrate with an acidic electrolyte containing copper ions, and cathodically biasing the semiconductor substrate, such that the protective layer is substantially dissolved, and copper is electroplated into the at least one recessed feature.

17. The method of claim 16, wherein the metal that is less noble than copper is cobalt, and wherein cobalt forms cobalt-oxygen bonds in the protective layer prior to electroplating.

18. The method of claim 16, wherein the protective layer has a thickness of between about 10-50 Å.

19. The method of claim 16, wherein (b) comprises initially contacting the semiconductor substrate with the acidic electrolyte without biasing the semiconductor substrate.

20. The method of claim 16, wherein the at least one recessed feature has a width of between about 7-14 nm.

21. The method of claim 19, wherein the at least one recessed feature has a width of between about 7-14 nm, and the protective layer has a thickness of between about 1-2 nm on the sidewalls of the at least one recessed feature.

22. An apparatus for processing a semiconductor substrate, the apparatus comprising:
(a) one or more process chambers configured for deposition of metals; and
(b) a controller comprising program instructions for causing deposition of a protective layer comprising a metal that is less noble than copper over a copper seed layer on the semiconductor substrate.

23. The apparatus of claim 22, wherein the metal that is less noble than copper is cobalt, and wherein the program instructions comprise instructions for causing deposition of cobalt by using a reaction of a cobalt-containing precursor.

24. The apparatus of claim 22, wherein the controller further comprises program instructions for causing a deposition of a copper seed layer prior to deposition of the protective layer.

25. The apparatus of claim 22, wherein the apparatus comprises a PVD process chamber configured for deposition of the copper seed layer, and a CVD process chamber configured for deposition of the protective layer, wherein the apparatus is configured for transferring the semiconductor substrate from the PVD process chamber to the CVD process chamber without exposing the semiconductor substrate to atmosphere.

26. The apparatus of claim 22, wherein the program instructions comprise instructions for depositing the protective layer at a thickness of between about 10-50 Å.
